(19) United States
(12) Patent Application Publication
(10) Pub. No.: US 2026/0126504 A1
(43) Pub. Date: May 7, 2026

(54) MAGNETIC RESONANCE IMAGING APPARATUS, DATA ACQUISITION METHOD, AND COMPUTER-READABLE, NONVOLATILE STORAGE MEDIUM STORING DATA ACQUISITION PROGRAM

(71) Applicant: CANON MEDICAL SYSTEMS CORPORATION, Otawara-shi (JP)

(72) Inventor: Hidenori TAKESHIMA, Taito Tokyo (JP)

(73) Assignee: CANON MEDICAL SYSTEMS CORPORATION, Otawara-shi (JP)

(21) Appl. No.: 19/372,597

(22) Filed: Oct. 29, 2025

(30) Foreign Application Priority Data
Nov. 1, 2024 (JP) 2024-192556
Sep. 17, 2025 (JP) 2025-153873

(51) Int. Cl. G01R 33/56; G01R 33/561

(52) U.S. Cl. CPC G01R 33/5607; G01R 33/5608; G01R 33/5617

(57) ABSTRACT

A magnetic resonance imaging apparatus according to one embodiment includes processing circuitry. The processing circuitry sets, in accordance with a preset repetition time (TR) or a duration for performing a suppression pulse train of suppression pulses to be applied for suppression of the same magnetic resonance signals, at least one or a combination of the number of the suppression pulses, flip angles of the suppression pulses, and pulse intervals between the suppression pulses. The processing circuitry acquires magnetic resonance data by performing a sequence including the suppression pulse train based on the number of the suppression pulses, the flip angles, and the pulse intervals.

### CROSS-REFERENCE TO RELATED APPLICATION

This application is based upon and claims the benefit of priority from Japanese Patent Application No. 2024-192556, filed on Nov. 1, 2024 and Japanese Patent Application No. 2025-153873, filed on Sep. 17, 2025; the entire contents of which are incorporated herein by reference.

### FIELD

Embodiments described herein relate generally to a magnetic resonance imaging apparatus, a data acquisition method, and a computer-readable, nonvolatile storage medium storing a data acquisition program.

### BACKGROUND

Conventionally, magnetic resonance spectroscopy (MRS) may adopt such methods as water suppression enhanced through T1 effects (WET) or VAriable Power and Optimized Relaxations delays (VAPOR) for water suppression pulse sequences to suppress water signals. VAPOR or a tuned version of VAPOR is a common choice for achieving higher water suppression effects in MRS.

The original VAPOR employs RF pulses with mainly two flip angles. In the original VAPOR, a sequence includes seven water suppression pulses. Thus, the VAPOR attains insensitivity to both T1 and ΔB1 by adjusting RF pulse timings. However, the original VAPOR can use only Gaussian pulses or sinc pulses as water suppression pulses since the design intervals among the water suppression pulses are too short. In the Gaussian pulses or sinc pulses, more frequencies result in offset flip angles from the design flip angles (i.e., imperfect slice profiles). In other words, due to imperfect slice profiles, the VAPOR may not be able to exert B1-insensitivity effects as designed. As such, in MRS using the conventional VAPOR, the imperfect slice profiles may result in degradation in water suppression performance.

In view of this, a variety of facilities or institutions adopt VAPOR with eight pulses (hereinafter, eight-pulse VAPOR) that is tuned (adjusted or regulated) original VAPOR. Even in the eight-pulse VAPOR, however, the ratio (characteristics) of attenuation of the water suppression pulses may vary depending on the flip angle relative to a T1 value or a criterion, which may make it difficult to use the eight-pulse VAPOR in MRS.

### BRIEF DESCRIPTION OF THE DRAWINGS

FIG. 1 is a schematic block diagram illustrating an exemplary configuration of a magnetic resonance imaging (MRI) apparatus according to a first embodiment;

FIG. 2 illustrates an example of optimized parameters Fₖ and Dₖ according to a first example;

FIG. 3 illustrates a result of characteristic analysis using the parameter set of FIG. 2 according to the first example, by way of example;

FIG. 4 illustrates an example of parameters Fₖ and Dₖ in original VAPOR as a first comparative example;

FIG. 5 illustrates a result of characteristic analysis using the parameter set of FIG. 4 according to the first comparative example, by way of example;

FIG. 6 illustrates an example of parameters Fₖ and Dₖ in eight-pulse VAPOR as a second comparative example;

FIG. 7 illustrates a result of characteristic analysis using the parameter set of FIG. 6 according to the second comparative example, by way of example;

FIG. 8 illustrates an example of optimized parameters when the minimum pulse interval is limited to 45 ms or more according to a second example;

FIG. 9 illustrates a result of characteristic analysis using the second optimized parameter set of FIG. 8 according to the second example, by way of example; and

FIG. 10 illustrates an example of optimized parameters for achieving suppression effects in a wider range according to a third example;

FIG. 11 illustrates a result of characteristic analysis using the third optimal parameter set of FIG. 10 according to the third example, by way of example;

FIG. 12 illustrates an example of optimized parameters using eight suppression pulses as a fourth example;

FIG. 13 illustrates a result of characteristic analysis using the fourth optimal parameter set of FIG. 12 according to the fourth example, by way of example;

FIG. 14 illustrates an example of optimized parameters using eight suppression pulses as a fifth example;

FIG. 15 illustrates a result of characteristic analysis using the fifth optimal parameter set of FIG. 14 according to the fifth example, by way of example;

FIG. 16 is a flowchart illustrating steps of a suppression sequence process according to the first embodiment, as an example;

FIG. 17 illustrates a functional configuration of processing circuitry according to a second embodiment, as an example;

FIG. 18 illustrates an example of optimized parameters using six suppression pulses as a sixth example;

FIG. 19 illustrates a result of characteristic analysis using the sixth optimal parameter set of FIG. 18 according to the sixth example, by way of example;

FIG. 20 illustrates an example of optimized parameters using seven suppression pulses as a seventh example;

FIG. 21 illustrates a result of characteristic analysis using the seventh optimal parameter set of FIG. 20 according to the seventh example, by way of example;

FIG. 22 illustrates an example of optimized parameters using eight suppression pulses according to an eighth example;

FIG. 23 illustrates a result of characteristic analysis using the eighth optimal parameter set of FIG. 22 according to the eighth example, by way of example; and

FIG. 24 is a flowchart illustrating steps of a suppression sequence execution process according to a second embodiment, as an example.

### DETAILED DESCRIPTION

A magnetic resonance imaging apparatus according to some embodiments includes processing circuitry. The processing circuitry is configured to set, in accordance with a preset repetition time (TR) or a duration for performing a suppression pulse train of suppression pulses to be applied for suppression of same magnetic resonance signals, at least one or a combination of a number of the suppression pulses, flip angles of the suppression pulses, and pulse intervals between the suppression pulses. The processing circuitry is configured to acquire magnetic resonance data by performing a sequence including the suppression pulse train based on the number of the suppression pulses, the flip angles, and the pulse intervals.

Hereinafter, exemplary embodiments of a magnetic resonance imaging (MRI) apparatus, a data acquisition method, and a data acquisition program will be described in detail with reference to the accompanying drawings. In principle, descriptions of one embodiment are applicable to another embodiment. Throughout the following embodiments, parts, portions, elements, or functions denoted by the same reference numerals are considered to perform same or similar operations, therefore, an overlapping explanation thereof will be omitted when appropriate. In addition, the following embodiments will describe an MRI apparatus for illustrative purpose only. As an example, a magnetic resonance spectroscopy (MRS) apparatus that can perform magnetic resonance spectroscopy is also applicable.

### First Embodiment

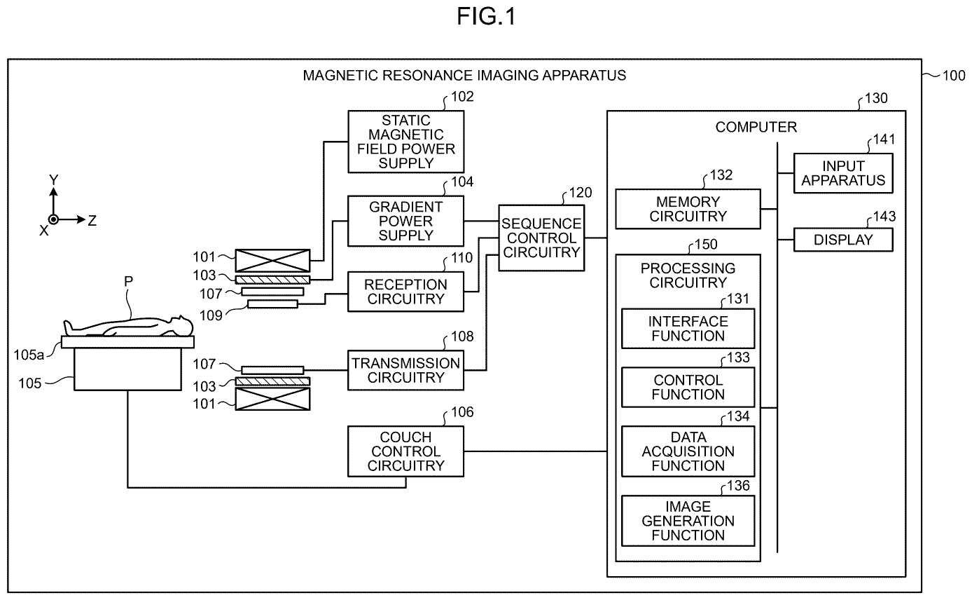

FIG. 1 is a block diagram of an exemplary configuration of an MRI apparatus 100 according to a first embodiment. As illustrated in FIG. 1, the MRI apparatus 100 includes static magnetic field magnets 101, a static magnetic field power supply 102, gradient coils 103, a gradient power supply 104, a couch 105, couch control circuitry 106, transmission coils 107, transmission circuitry 108, a reception coil 109, reception circuitry 110, sequence control circuitry 120, and a computer (also referred to as image processing apparatus) 130. The MRI apparatus 100 does not include a subject P (such as a human body). The structure and configuration illustrated in FIG. 1 are merely exemplary. As an example, the elements of the sequence control circuitry 120 and of the computer 130 may be integrated or separated when appropriate.

The static magnetic field magnets 101 are hollow, substantially cylindrical magnets to generate static magnetic fields in the internal space. Examples of the static magnetic field magnet 101 include a superconducting magnet that magnetizes, supplied with a current from the static magnetic field power supply 102. The static magnetic field power supply 102 supplies currents to the static magnetic field magnets 101. The static magnetic field magnets 101 can be permanent magnets. In this case the MRI apparatus 100 may not include the static magnetic field power supply 102. In addition, the static magnetic field power supply 102 may be separated from the MRI apparatus 100.

The gradient coils 103 are hollow, substantially cylindrical coils and disposed inside the static magnetic field magnets 101. Each gradient coil 103 is a combination of three coils corresponding to mutually orthogonal X-axis, Y-axis, and Z-axis. The three coils are individually supplied with currents from the gradient power supply 104, to generate gradient fields that vary in field strength along the X, Y, and Z-axes. The gradient fields generated along the X, Y, and Z-axes by the gradient coils 103 are exemplified by a slice gradient field Gs, a phase-encoding gradient field Ge, and a readout gradient field Gr. The gradient power supply 104 supplies currents to the gradient coils 103.

The couch 105 includes a couchtop 105a on which the subject P is to be laid. Under the control of the couch control circuitry 106, the couch 105 with the subject P lying thereon is inserted into a hollow space (imaging region) of the gradient coils 103. The couch 105 is typically installed in such a manner that its longitudinal side is parallel to the axes of the static magnetic field magnets 101. The couch control circuitry 106 drives the couch 105 to move the couchtop 105a longitudinally and vertically under the control of the computer 130.

The transmission coils 107 are located inside the gradient coils 103, to generate high-frequency magnetic fields, supplied with an RF pulse from the transmission circuitry 108. The transmission circuitry 108 supplies RF pulses corresponding to the Larmor frequency to the transmission coils 107. The Larmor frequency is defined by a type of target atoms and a magnetic field strength.

The reception coil 109 is located inside the gradient coils 103, to receive magnetic resonance (MR) signals which are issued from the subject P due to an influence of the high-frequency magnetic fields. The reception coil 109 outputs the MR signals to the reception circuitry 110 upon receipt.

The transmission coils 107 and the reception coil 109 as described above are presented for illustrative purpose only. Each of the transmission coils 107 and the reception coil 109 may be one or a combination of a coil having a transmission function alone, a coil having a reception function alone, and a coil having both transmission and reception functions.

The reception circuitry 110 detects MR signals output from the reception coil 109 and generate MR data from the detected MR signals. Specifically, the reception circuitry 110 generates MR data by converting the MR signals output from the reception coil 109 into digital signals. The reception circuitry 110 transmits the MR data to the sequence control circuitry 120. The reception circuitry 110 may be included in a gantry equipped with the static magnetic field magnets 101, the gradient coils 103, and other elements.

The sequence control circuitry 120 performs imaging of the subject P by driving the gradient power supply 104, the transmission circuitry 108, and the reception circuitry 110 based on sequence information transmitted from the computer 130. Herein, the sequence information is information representing defined imaging procedures and may also be referred to as a sequence condition. The sequence information includes definitions of current intensity and current supply timing from the gradient power supply 104 to the gradient coils 103, RF pulse intensity and RF pulse application timing from the transmission circuitry 108 to the transmission coils 107, and MR-signal detection timing by the reception circuitry 110, for example.

Examples of the sequence control circuitry 120 include integrated circuitry such as an application specific integrated circuit (ASIC) and a field programmable gate array (FPGA), and electronic circuitry such as a central processing unit (CPU) and a micro processing unit (MPU). The sequence control circuitry 120 corresponds to a sequence control unit.

After driving the gradient power supply 104, the transmission circuitry 108, and the reception circuitry 110 to image the subject P, the sequence control circuitry 120 receives resultant MR data from the reception circuitry 110 and transfers the MR data to the computer 130.

The computer 130 performs overall control of the MRI apparatus 100 and generates images, for example. The computer 130 includes memory circuitry 132, an input apparatus 141, a display 143, and processing circuitry 150. The processing circuitry 150 includes an interface function 131, a control function 133, a data acquisition function 134, and an image generation function 136.

Processing and functions to be performed by the interface function 131, the control function 133, the data acquisition function 134, and the image generation function 136 are stored in the memory circuitry 132 in the form of a computer program executable by the computer 130. The processing circuitry 150 is a processor that retrieves and executes the computer programs from the memory circuitry 132 to implement the functions corresponding to the respective computer programs. In other words, having retrieved the computer programs, the processing circuitry 150 includes the respective functions shown in the processing circuitry 150 of FIG. 1.

FIG. 1 depicts an example that the single piece of processing circuitry 150 implements the processing and functions of the interface function 131, the control function 133, the data acquisition function 134, and the image generation function 136. Alternatively, the processing circuitry 150 may be constituted of a combination of independent processors so that the processors can individually implement the functions by executing the computer programs. In other words, the above functions may be configured as individual computer programs to be executed by the single piece of processing circuitry 150, or particular function or functions may be incorporated in dedicated, independent program-executable circuitry.

The term “processor” used herein signifies, for example, circuitry such as a CPU, a graphical processing unit (GPU), an application specific integrated circuit, a programmable logic device (e.g., simple programmable logic device (SPLD)), a complex programmable logic device (CPLD), and a field programmable gate array (FPGA). The processor retrieves and executes the computer programs from the memory circuitry 132 to implement the functions.

In place of being stored in the memory circuitry 132, the computer programs may be directly embedded in the circuitry of the processor. In such a case the processor retrieves and executes the computer programs from the internal circuitry to implement the functions. Likewise, the couch control circuitry 106, the transmission circuitry 108, the reception circuitry 110, and the sequence control circuitry 120 each include electronic circuitry such as the above processor.

The processing circuitry 150 uses the interface function 131 to transmit sequence information to the sequence control circuitry 120 and receive MR data from the sequence control circuitry 120. Upon receipt of the MR data, the interface function 131 of the processing circuitry 150 stores the MR data in the memory circuitry 132. The processing circuitry 150 implementing the interface function 131 corresponds to an interface unit.

The processing circuitry 150 uses the control function 133 to control the MRI apparatus 100 as a whole and control imaging, image generation, image display, and else. For example, the processing circuitry 150 uses the control function 133 to receive an input of an imaging condition (imaging parameters, etc.) via the GUI and to generate sequence information according to the received imaging condition. The processing circuitry 150 uses the control function 133 to transmit the generated sequence information to the sequence control circuitry 120. In the present embodiment, the control function 133 transmits information as to a sequence including a series of at least seven suppression pulses (sequence information) to the sequence control circuitry 120.

The suppression pulses are intended for suppressing occurrence of MR signals due to an excitation pulse. For example, the suppression pulses work to suppress water signals (hereinafter, water suppression pulses). The suppression pulses may be, for example, suppression pulses for fat signals (hereinafter, fat suppression pulses), in addition to the water suppression pulses. In the following, the suppression pulses are defined as water suppression pulses for the sake of specificity. The sequence including a series of at least seven suppression pulses (hereinafter, water suppression sequence) will be explained later. For simpler explanation, the number of a series of suppression pulses in the water suppression sequence is defined to be seven. The processing circuitry 150 implementing the control function 133 corresponds to a control unit.

The processing circuitry 150 uses the data acquisition function 134 to acquire magnetic resonance (MR) data by performing the sequence including a series of at least seven suppression pulses. As an example, the data acquisition function 134 acquires MR data by imaging based on the water suppression sequence from the sequence control circuitry 120. The data acquisition function 134 stores the acquired MR data (also referred to as k-space data) in the memory circuitry 132. The processing circuitry 150 implementing the data acquisition function 134 corresponds to a data acquisition unit.

The processing circuitry 150 uses the image generation function 136 to generate MR images by retrieving MR data (k-space data) from the memory circuitry 132 and applying reconstruction processing such as the Fourier transform to the k-space data. Any of known methods is applicable to the MR image generation, therefore, a description thereof is omitted. The processing circuitry 150 implementing the image generation function 136 corresponds to an image generator unit.

The following will explain optimization of a series of seven suppression pulses contained in a water suppression sequence. Longitudinal magnetization in the equilibrium state at a time t is defined as B_{z}(t) and B₀. A flip angle of a k^{th} suppression pulse is defined as αFₖ where k=1, . . . , K. K is 7 since the number of the series of suppression pulses is seven. An angle α (hereinafter, a reference angle) of a flip angle αFₖ may be set to, for example, 90, 80, or 100 degrees by pre-adjustment based on heterogeneous information as to a target RF magnetic field (transmit B1) to which the suppression sequence is applied, or by adjustment through optimal-value inference from calibration scanning. Fₖ represents a parameter by which the angle α is multiplied.

Further, a duration from a k^{th} RF pulse (suppression pulse) to the next RF pulse (suppression pulse or excitation pulse) in the water suppression sequence is denoted by Dₖ. Also, a longitudinal relaxation time of a target cell to which the water suppression sequence is applied is denoted by T₁. The duration Dₖ corresponds to an interval with no suppression pulses applied and may be referred to as a pulse non-application period or a waiting period. The duration Dₖ corresponds to an adjustable parameter in the water suppression sequence. It is assumed that the duration of an RF pulse (suppression pulse) be zero and a gradient field spoiler in the water suppression sequence ideally function. Then, longitudinal magnetization B_{Z}(tₖ₊₁) at a (k+1)^{th} time is represented by the following Equation (1):

$${B}_{z} ( {t}_{k + 1} ) = {B}_{0} + {B}_{z} ( {t}_{k} ) cos ( α {F}_{k} - {B}_{0} ) exp ( - {D}_{k} / {T}_{1} ) \qquad ( 1 )$$

In Equation (1) tₖ₊₁ is a sum of durations Dₘ (tₖ₊₁=Σₘ=1^{k}(Dₘ)) from (m−1) to k and indicates a time of a k^{th} RF pulse. The parameters Fₖ and Dₖ are set by minimization of the longitudinal magnetization B_{Z}(tₖ₊₁), i.e., optimizing the right side of Equation (1) to a minimum.

The criterion for the optimization is represented by, for example, minimization of Equation (2) as below:

$$\text{?} {\sum }_{{T}_{1}} \vert {B}_{z} ( {t}_{k + 1} ) \vert \qquad ( 2 )$$

$$\text{?} \text{indicates text missing or illegible when filed}$$

In the minimization of Equation (2), seven parameters Fₖ and seven parameters Dₖ are to be adjusted. Namely, vectors to be optimized in Equation (2) are 14-dimensional vectors of Fₖ and Dₖ. It is not easy to directly optimize the criterion, so that a constraint condition being not to be less than 45 ms is imposed on Dₖ, for example. Under such a constraint condition, the parameters are determined by searching various initial vectors by greedy algorithms or by a known nonlinear function optimization method, for instance. The determined parameters are stored in the memory circuitry 132.

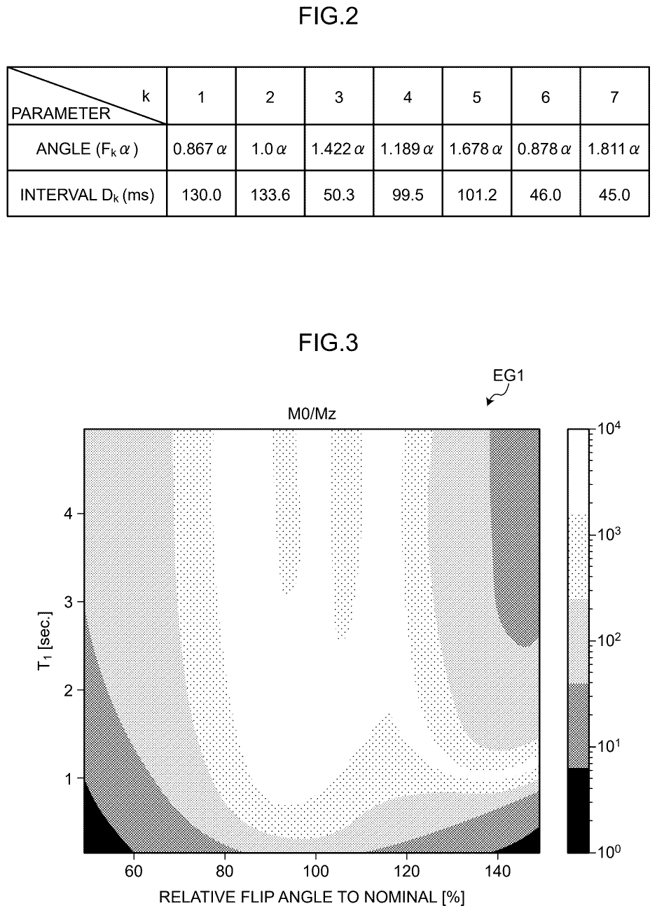

FIG. 2 depicts an example of optimized parameters Fₖ and Dₖ as a first example. The average of the intervals Dₖ is 86.5 ms, and a total length of time (a sum of the intervals Dₖ (ΣₖDₖ)) from a start of application of water suppression pulses to application of an excitation pulse is 605.6 ms. The flip angles of the seven water suppression pulses are set to 0.867×α, 1.0×α, 1.422×α, 1.189×α, 1.678×α, 0.878×α, and 1.811×α in the order of application thereof (the order of k), where α is a reference angle. The intervals (ms) between two respective adjacent ones of the seven water suppression pulses and the interval (ms) between the last one of the water suppression pulses and the excitation pulse are 130.0, 133.6, 50.3, 99.5, 101.2, 46.0, and 45.0 in the order of application of the water suppression pulses.

FIG. 3 is a graph depicting a result of characteristic analysis using the parameter set (hereinafter, a first optimal parameter set) shown in FIG. 2 according to the first example, as an example. In FIG. 3 the result of characteristic analysis in the first example was computed through a simulation using the first optimal parameter set when α=90 degrees, for example. The characteristic analysis result is also referred to as a slice profile. In the graph EG1 of FIG. 3 showing the characteristic analysis result in the first example, the vertical axis indicates a T1 value and the horizontal axis indicates a ratio of flip angles in the simulation to nominal flip angles (design flip angles). For example, the T1 value of cerebrospinal fluid (CSF) is about 4.0 while the T1 values of grey matter (GM) and white matter (WM) are about 0.8 to 1.5.

In the graph EG1 of FIG. 3 of the first example, the ratios of attenuation of the water suppression pulses are indicated by different kinds of hatching. In a colored graph EG1 of FIG. 3, attenuation of 1/10,000 is represented in green, attenuation of about 1/1,000 is represented in intermediate color (orange) between red and green, and attenuation of about 1/100 is represented in red, attenuation of about 1/10 is represented in purple, and attenuation of about 1.0 is represented in blue. As such, the green region indicates preferable attenuation characteristics.

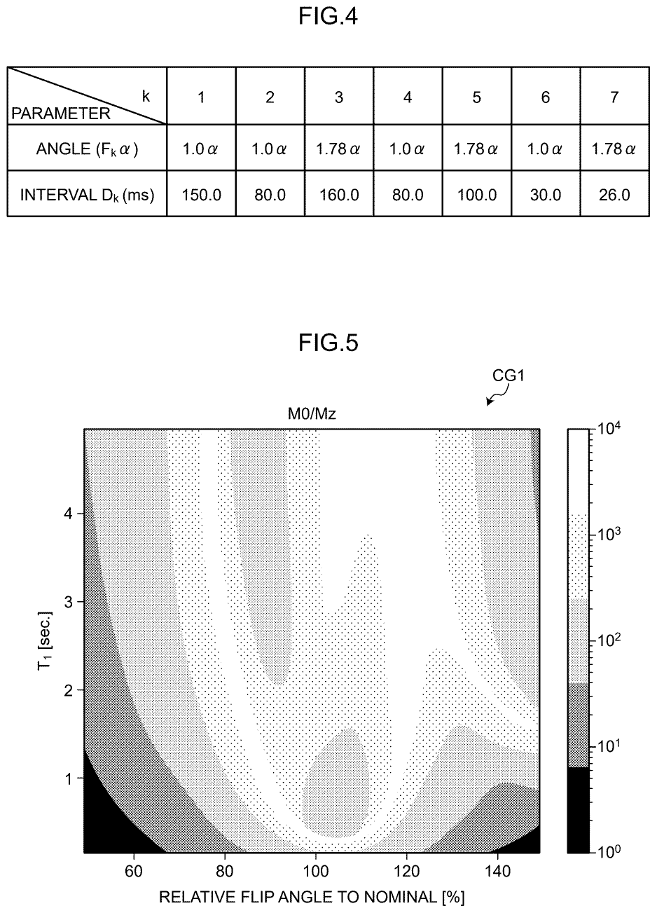

FIG. 4 depicts an example of parameters Fₖ and Dₖ in the original VAPOR as a first comparative example. The average of the intervals Dₖ is 89.4 ms and the sum of the intervals Dₖ (ΣₖDₖ) is 626.0 ms. The flip angles of the seven water suppression pulses are set to 1.0×α, 1.0×α, 1.78×α, 1.0×α, 1.78×α, 1.0×α, and 1.78×α in the order of application thereof (the order of k), where α is a reference angle. The intervals (ms) between two respective adjacent ones of the seven water suppression pulses and the interval (ms) between the last one of the water suppression pulses and the excitation pulse are 150.0, 80.0, 160.0, 80.0, 100.0, 30.0, and 26.0 in the order of application of the water suppression pulses.

FIG. 5 is a graph depicting a result of characteristic analysis using the parameter set (hereinafter, a first comparative parameter set) shown in FIG. 4 according to the first comparative example, as an example. In FIG. 5 the result of characteristic analysis in the first comparative example was computed through a simulation using the first comparative parameter set when α=90 degrees, for example. In the graph CG1 showing the result of characteristic analysis in FIG. 5, the vertical axis, horizontal axis, and different kinds of hatching indicate the same items as in FIG. 3.

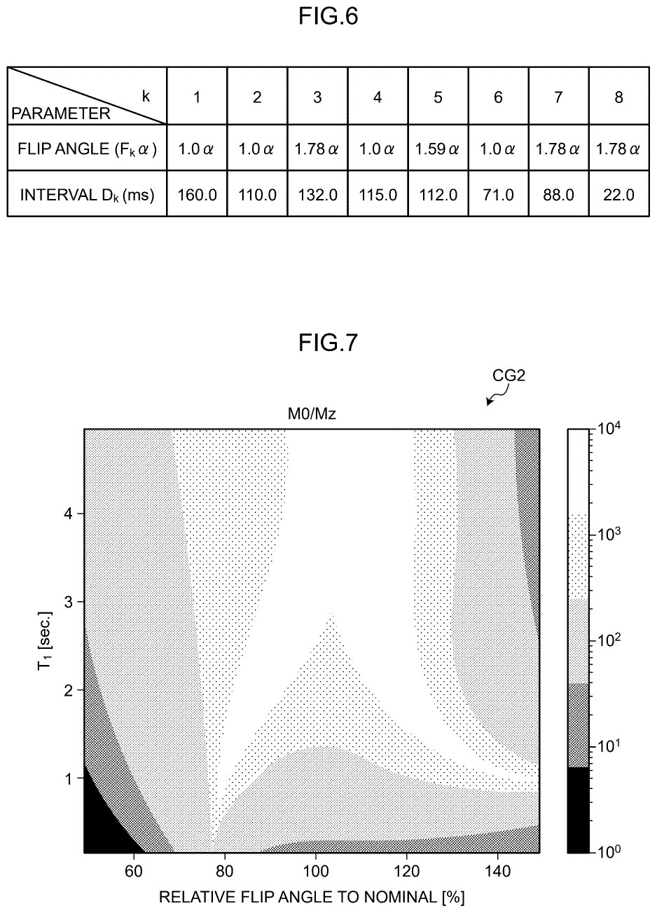

FIG. 6 depicts an example of parameters Fₖ and Dₖ in eight-pulse VAPOR as a second comparative example, based on a technique disclosed in Document 1: Tka'c I, Andersen P, Adriany G, Merkle H, Ugurbil K, Gruetter R., “In vivo 1H NMR spectroscopy of the human brain at 7T”, Magn Reson Med. 2001 September; 46(3):451-6. doi: 10.1002/mrm.1213) and in Document 2: Deelchand D K, Berrington A, Noeske R, Joers J M, Arani A, Gillen J, Schär M, Nielsen J F, Peltier S, Seraji-Bozorgzad N, Landheer K, Juchem C, Soher B J, Noll D C, Kantarci K, Ratai E M, Mareci T H, Barker P B, Öz G, “Across-vendor standardization of semi-LASER for single-voxel MRS at 3T”, NMR Biomed. 2021 May; 34(5): e4218. doi: 10.1002/nbm.4218. The average of the intervals Dₖ is 101.2 ms and the sum of the intervals Dₖ (ΣₖDₖ) is 810.0 ms. The flip angles of the eight water suppression pulses are set to 1.0×α, 1.0×α, 1.78×α, 1.0×α, 1.59×α, 1.0×α, 1.78×α, and 1.78×α in the order of application thereof (the order of k), where α is a reference angle. The intervals (ms) between two respective adjacent ones of the eight water suppression pulses and the interval (ms) between the last one of the water suppression pulses and the excitation pulse are 160.0, 110.0, 132.0, 115.0, 112.0, 71.0, 88.0, and 22.0 in the order of application of the water suppression pulses.

FIG. 7 a graph depicting a result of characteristic analysis using the parameter set (hereinafter, a second comparative parameter set) shown in FIG. 6 according to the second comparative example, as an example. In FIG. 7 the result of characteristic analysis in the second comparative example was computed through a simulation using the second comparative parameter set when α=90 degrees, for example. In the graph CG2 showing the result of characteristic analysis in FIG. 7, the vertical axis, horizontal axis, and different kinds of hatching indicate the same items as in FIG. 3 and FIG. 5.

In comparison, the graph EG1 showing the characteristic analysis result of FIG. 3 in the first example has a wider 1/10,000 attenuation area than the graph CG1 of FIG. 5 in the first comparative example and the graph CG2 of FIG. 7 in the second comparative example. In particular, in the graph EG1 showing the characteristic analysis result of the first example, attenuation of 1/10,000 is observed in a ±20% area (80% to 120%) with reference to the design flip angle (position corresponding to 100% on the horizontal axis), which signifies higher suppression effects than in the first and second comparative examples.

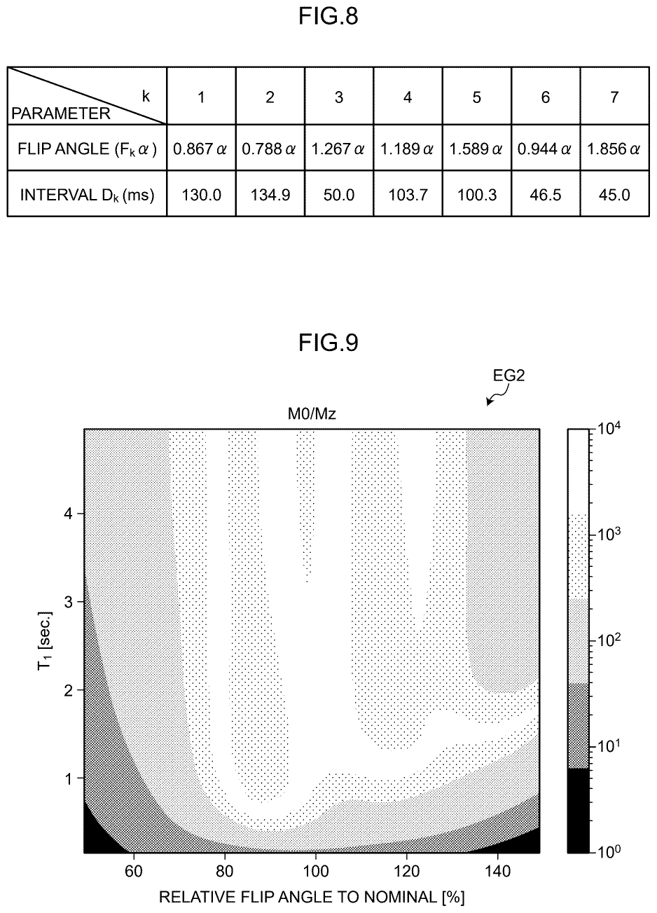

The parameters Fₖ and Dₖ of the present embodiment are not limited to the first optimal parameter set of the first example in FIG. 2. FIG. 8 depicts an example of optimized parameters (hereinafter, a second optimal parameter set) according to the second example, when the minimal pulse interval is limited to 45 ms or more. The average of the intervals Dₖ is 87.2 ms, and the total length of time (sum of the intervals Dₖ (ΣₖDₖ)) from a start of application of water suppression pulses to application of an excitation pulse is 610.4 ms. The flip angles of the seven water suppression pulses are set to 0.867×α, 0.788×α, 1.267×α, 1.189×α, 1.589×α, 0.944×α, and 1.856×α in the order of application thereof (the order of k), where α is a reference angle. The intervals (ms) between two respective adjacent ones of the seven water suppression pulses and the interval (ms) between the last one of the water suppression pulses and the excitation pulse are 130.0, 134.9, 50.0, 103.7, 100.3, 46.5, and 45.0 in the order of application of the water suppression pulses.

FIG. 9 is a graph depicting a result of characteristic analysis using the second optimal parameter set shown in FIG. 8 according to the second example, as an example. In FIG. 9 the result of characteristic analysis in the second example was computed through a simulation using the second optimal parameter set when α=90 degrees, for example. In the graph EG2 showing the result of characteristic analysis in FIG. 9 in the second example, the vertical axis, horizontal axis, and different kinds of hatching indicate the same items as in FIGS. 3, 5, and 7.

In comparison, the graph EG2 showing the characteristic analysis result of FIG. 9 in the second example has a wider 1/10,000 attenuation area than the graph CG1 of FIG. 5 in the first comparative example and the graph CG2 of FIG. 7 in the second comparative example. According to the characteristic analysis result in the graph EG2 of FIG. 9 in the second example, thus, it can be said that the signal suppression effects of the suppression pulses in the second example are improved from those in the first and second comparative examples although they may be lower than the effects of the first optimal parameter set.

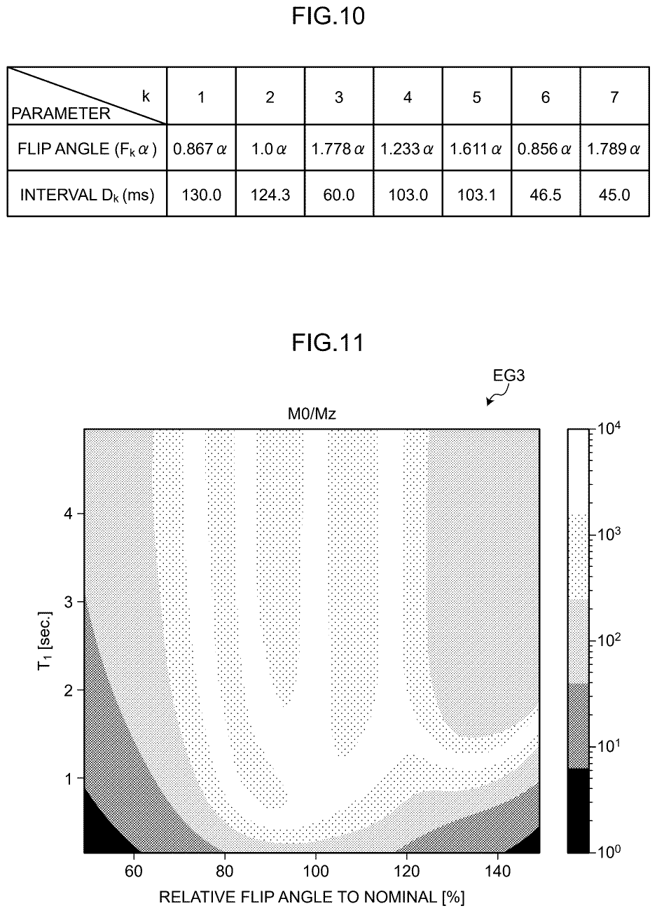

In addition, the parameters may be optimized so as to attain the signal suppression effects of the suppression pulses in a wider range. FIG. 10 depicts an example of optimized parameters (hereinafter, a third optimal parameter set) for attaining the suppression effects in a wider range according to a third example. The average of the intervals Dₖ is 87.4 ms, and the total length of time (sum of the intervals Dₖ (ΣₖDₖ)) from a start of application of water suppression pulses to application of an excitation pulse is 611.9 ms. The flip angles of the seven water suppression pulses are set to 0.867×α, 1.0×α, 1.778×α, 1.233×α, 1.611×α, 0.856×α, and 1.789×α in the order of application thereof (the order of k), where α is a reference angle. The intervals (ms) between two respective adjacent ones of the seven water suppression pulses and the interval (ms) between the last one of the water suppression pulses and the excitation pulse are 130.0, 124.3, 60.0, 103.0, 103.1, 46.5, and 45.0 in the order of application of the water suppression pulses.

FIG. 11 is a graph depicting a result of characteristic analysis using the third optimal parameter set shown in FIG. 10 according to the third example, as an example. In FIG. 11 the result of characteristic analysis in the third example was computed through a simulation using the third optimal parameter set, for example. In the graph EG3 showing the result of characteristic analysis in FIG. 11, the vertical axis, horizontal axis, and different kinds of hatching indicate the same items as in FIGS. 3, 5, 7, and 9.

In comparison, the graph EG3 showing the characteristic analysis result of FIG. 11 in the third example has a wider attenuation area of 1/10,000 to 1/1,000 than the graph CG1 of FIG. 5 in the first comparative example and the graph CG2 of FIG. 7 in the second comparative example. According to the characteristic analysis result in the graph EG3 of FIG. 11 in the third example, thus, it can be said that the signal suppression effects of the suppression pulses in the third example are improved from those in the first and second comparative examples although they may be lower than the effects of the first optimal parameter set and the second optimal parameter set. Moreover, in the graph EG3 showing the characteristic analysis result of the third example in FIG. 11, the signal suppression effects of the suppression pulses are observed in a wider range than those of the first optimal parameter set and the second optimal parameter set, and are higher than the signal suppression effects attained in the first and second comparative examples.

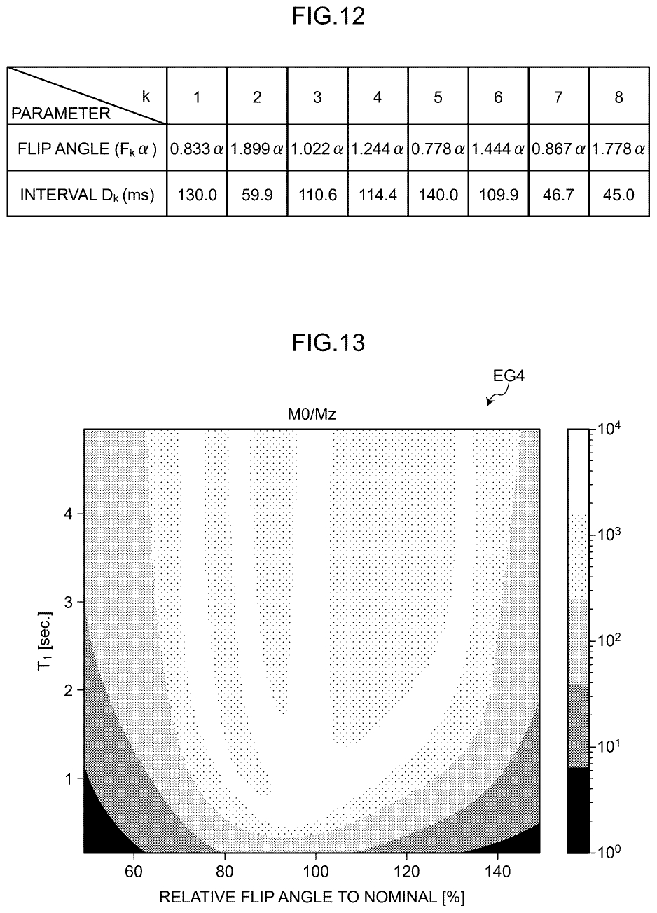

The present invention is also beneficial in the use of eight suppression pulses. As an example, FIG. 12 depicts an example of parameters (hereinafter, a fourth optimal parameter set) for use of eight suppression pulses as a fourth example. The average of the intervals Dₖ is 94.6 ms, and the total length of time (sum of the intervals Dₖ (ΣₖDₖ)) from a start of application of water suppression pulses to application of an excitation pulse is 756.5 ms. The flip angles of the eight water suppression pulses are set to 0.833×α, 1.899×α, 1.022×α, 1.244×α, 0.788×α, 1.444×α, 0.867×α, and 1.778×α in the order of application thereof (the order of k), where α is a reference angle. The intervals (ms) between two respective adjacent ones of the eight water suppression pulses and the interval (ms) between the last one of the water suppression pulses and the excitation pulse are 130.0, 59.9, 110.6, 114.4, 140.0, 109.9, 46.7, and 45.0 in the order of application of the water suppression pulses.

FIG. 13 is a graph depicting a result of characteristic analysis using the fourth optimal parameter set shown in FIG. 12 according to the fourth example, as an example. In FIG. 13 the result of characteristic analysis in the fourth example was computed through a simulation using the fourth optimal parameter set, for example. In the graph EG4 showing the result of characteristic analysis in FIG. 13, the vertical axis, horizontal axis, and different kinds of hatching indicate the same items as in FIGS. 3, 5, 7, 9, and 11.

In comparison, the graph EG4 showing the characteristic analysis result of FIG. 13 in the fourth example has a wider attenuation area of 1/10,000 to 1/1,000 than the graph CG1 of FIG. 5 in the first comparative example and the graph CG2 of FIG. 7 in the second comparative example. According to the graph EG4 showing the characteristic analysis result of FIG. 13 in the fourth example, thus, it can be said that the signal suppression effects of the suppression pulses in the fourth example are improved from those in the first and second comparative examples.

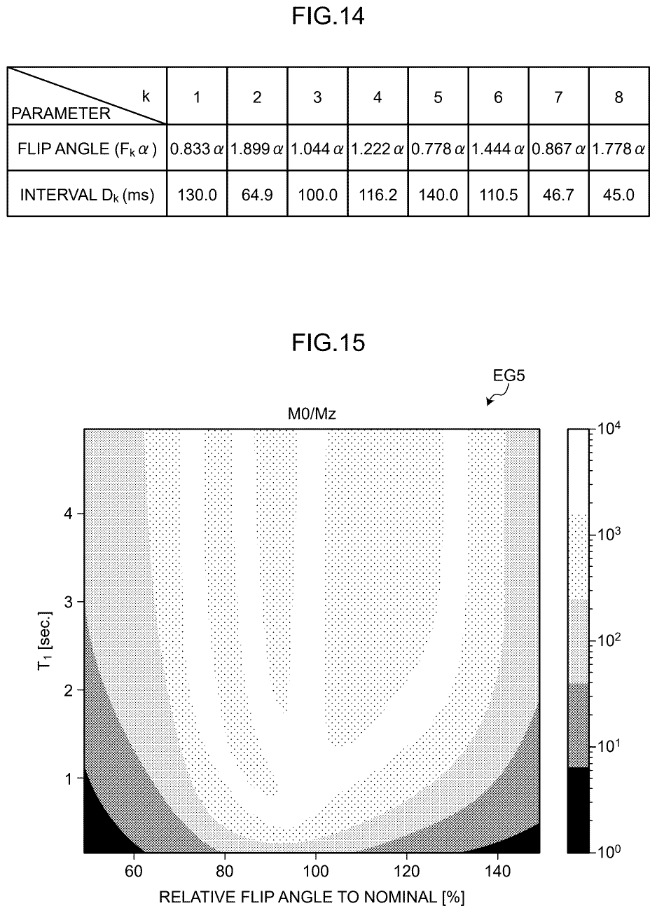

Another exemplary use of the eight suppression pulses is now explained. FIG. 14 depicts an example of different parameters (hereinafter, a fifth optimal parameter set) for the use of eight suppression pulses as a fifth example. The average of the intervals Dₖ is 94.2 ms, and the total length of time (sum of the intervals Dₖ (ΣₖDₖ)) from a start of application of water suppression pulses to application of an excitation pulse is 753.3 ms. The flip angles of the eight water suppression pulses are set to 0.833×α, 1.899×α, 1.044×α, 1.222×α, 0.788×α, 1.444×α, 0.867×α, and 1.778×α in the order of application thereof (the order of k), where α is a reference angle. The intervals (ms) between two respective adjacent ones of the eight water suppression pulses and the interval (ms) between the last one of the water suppression pulses and the excitation pulse are 130.0, 64.9, 100.0, 116.2, 140.0, 110.5, 46.7, and 45.0 in the order of application of the water suppression pulses.

FIG. 15 is a graph depicting a result of characteristic analysis using the fifth optimal parameter set shown in FIG. 14 according to the fifth example, as an example. In FIG. 15 the result of characteristic analysis in the fifth example was computed through a simulation using the fifth optimal parameter set, for example. In the graph EG5 showing the result of characteristic analysis in FIG. 15, the vertical axis, horizontal axis, and different kinds of hatching indicate the same items as in FIGS. 3, 5, 7, 9, 11, and 13.

In comparison, the graph EG5 showing the characteristic analysis result of FIG. 15 in the fifth example has a wider attenuation area of 1/10,000 to 1/1,000 than the graph CG1 of FIG. 5 in the first comparative example and the graph CG2 of FIG. 7 in the second comparative example. According to the characteristic analysis result in the graph EG5 of FIG. 15 in the fifth example, thus, it can be said that the signal suppression effects of the suppression pulses in the fifth example are improved from those in the first and second comparative examples.

In the first to fifth optimal parameter sets, the multiple suppression pulses have different flip angles, unlike those in the first and second comparative examples. Namely, the flip angles of the multiple suppression pulses are all different. In the first to fifth examples, thus, a signal suppressible sequence (suppression sequence) is constituted of seven or more RF pulses (suppression pulses) with mutually different flip angles.

In addition, with respect to each of the first to fifth optimal parameter sets in the first to fifth examples, the interval (ms) between the last one of the water suppression pulses (last suppression pulse) and the excitation pulse, i.e., the interval at the maximal value of k (e.g., D₇ when there are seven suppression pulses), is longer than that in the first comparative example and the second comparative example. The length of the interval represents, for example, a duration during which at least one prepulse is applicable. Specifically, the interval between the last one of the suppression pulses and the excitation pulse may be set to 45 ms or more, for instance, and represents a time interval during which one or more prepulses can be applied while suppressing occurrence of MR signals resulting from the excitation pulse by using the series of suppression pulses.

As such, it is made possible to arrange one or more prepulses between the last one of the series of suppression pulses and the excitation pulse in the suppression sequence. Examples of the prepulses include outer volume suppression (OVS) pulses for use in OVS. OVS is a technique for applying saturation signals as prepulses to signals from unintended signal sources outside a region of interest to suppress the signals from outside the region of interest. The prepulses can be another type of prepulses depending on an intended use, in addition to the OVS pulses.

Further, in the suppression sequences of the first to fifth examples, one of the intervals (D₁ to D₃) between two respective adjacent ones of the front half of the series of suppression pulses depicted in FIGS. 2, 8, 10, 12, and 14 is shorter than the intervals (D₁ to D₃) between two respective adjacent ones of the front half of the series of suppression pulses by the VAriable Power and Optimized Relaxations delays (VAPOR) method in the first comparative example of FIG. 4 and the second comparative example of FIG. 6.

Namely, the VAPOR method of FIG. 4 in the first comparative example and a variation of the VAPOR method of FIG. 6 in the second comparative example adopt prepulses consisting of a train of seven or more saturation pulses (suppression pulses). Also, the saturation pulses (suppression pulses) have two different flip angles, as depicted in FIG. 4 in the first comparative example and in FIG. 6 in the second comparative example. When D₁ to D₃ are defined as the front half of the sequence, the pulse interval is found as 80 ms at a minimum, as shown in FIG. 4 in the first comparative example and FIG. 6 in the second comparative example. When D₅ to D₇ are defined as the rear half of the sequence, the pulse interval is found as 26 ms at a minimum, as depicted in FIG. 4 in the first comparative example and in FIG. 6 in the second comparative example.

The term “front half” refers to a part of the chronological series of suppression pulses in the suppression sequence, the part being to be applied at times prior to a chronologically central time. Similarly, the term “rear half” refers to a part of the chronological series of suppression pulses in the suppression sequence, the part being to be applied at times subsequent to the chronologically central time.

More specifically, the pulse intervals in the first to fifth examples are D₃=50.3 ms in the first optimal parameter set, D₂=50.0 ms in the second optimal parameter set, D₂=59.9 ms in the third optimal parameter set, D₂=59.9 ms in the fourth example optimal parameter set, and D₂=64.9 ms in the fifth example optimal parameter set, respectively, and they are all shorter than any of the intervals (D₁=150.0 ms, D₂=80.0 ms, D₃=160.0 ms) of the front half of the first comparative parameter set in the first comparative example and any of the intervals (D₁=160.0 ms, D₂=110.0 ms, D₃=132.0 ms, D₄=115.0 ms) of the front half of the second comparative parameter set in the second comparative example. As such, according to the first embodiment including the first to fifth examples, at least one of the pulse intervals between two respective adjacent suppression pulses of the front half of the chronological series of suppression pulses is defined as 70 ms or less and preferably 60 ms or less as in the first to fourth examples.

In each of the first to fifth optimal parameter sets, the irradiation time of each of at least seven or more suppression pulses is not zero. Because of this, the pulses based on the first to fifth optimal parameter sets in the first to fifth examples may be offset from their ideal pulses. In view of this, the last intervals in the first to fifth optimal parameter sets may be finely adjusted to eliminate such offsets. For instance, the interval of 45 ms between the last one of the water suppression pulses and the excitation pulses may be changed to an optimal value of 46 ms or 44 ms before execution of the suppression pulse sequence. Alternatively, multiple pieces of data may be obtained at the finely adjusted, last one of the intervals while the suppression pulse sequence is running, to finely adjust the last interval based on the obtained data. A known method as the VAPOR method can be adopted for this fine adjustment method.

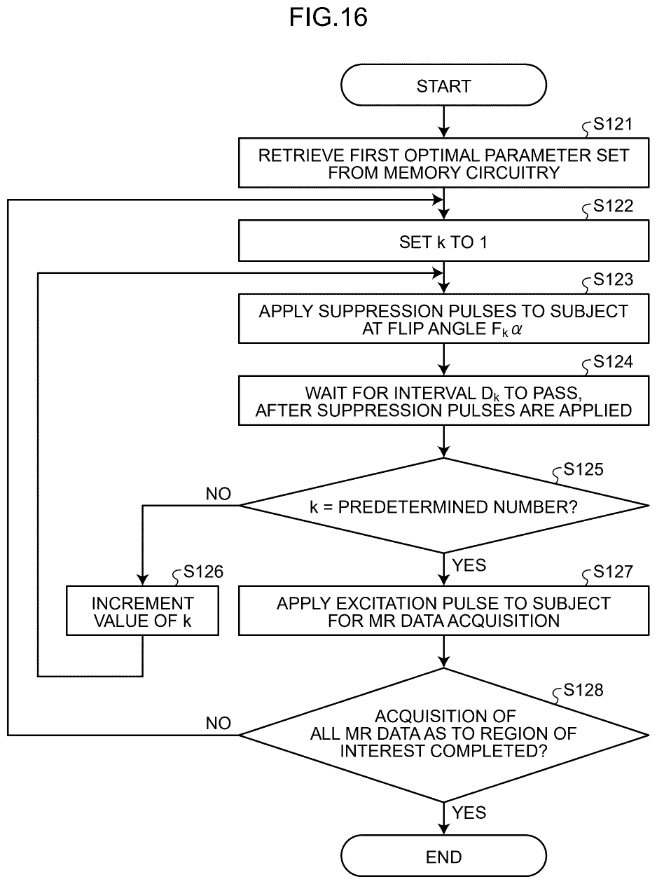

The overall configuration and structure of the magnetic resonance imaging apparatus 100 have been described above. The following will describe the steps of a water suppression sequence process (hereinafter, a suppression sequence process) to be performed by the magnetic resonance imaging apparatus 100. FIG. 16 is a flowchart illustrating the steps of the suppression sequence process, by way of example. The suppression sequence process is for acquiring MR data by running a sequence including a predetermined number, e.g., seven or more (at least seven) suppression pulses. For the sake of specificity, the number of suppression pulses is predetermined as seven or more. The water suppression sequence is defined to be run in accordance with the first optimal parameter set, for example. The number of suppression pulses may be set to eight, instead of seven as in the first optimal parameter set.

### Suppression Sequence Process

### Step S121

Prior to running the water suppression sequence, the processing circuitry 150 retrieves the first optimal parameter set from the memory circuitry 132. For this purpose, the interval D₇ may be finely adjusted in advance, for instance. The reference angle α is set by the input apparatus 141 or an examination order, depending on a region of the subject P to be imaged.

### Step S122

“k” defining the suppression pulse number and the interval number is set to 1.

### Step S123

The sequence control circuitry 120 controls the transmission circuitry 108 to generate suppression pulses at a flip angle αFₖ. The transmission circuitry 108 applies the suppression pulses to the subject P.

### Step S124

After applying the suppression pulses at the flip angle αFₖ, the sequence control circuitry 120 controls the transmission circuitry 108 to wait for the interval Dₖ to pass.

### Step S125

If the value of k defining the suppression pulse number and the interval number does not match the predetermined number (No in Step S125), the flow proceeds to step S126. If the value of k defining the suppression pulse number and the interval number matches the predetermined number (Yes in Step S125), the flow proceeds to step S127.

### Step S126

The value of k is incremented. After step S126, the processing in step S123 and the subsequent steps is iterated.

### Step S127

After a lapse of the last interval (e.g., D₇ when there are seven suppression pulses) from the application of the last suppression pulse, the sequence control circuitry 120 controls the transmission circuitry 108 to apply the excitation pulse to the subject P. During the interval D₇, the sequence control circuitry 120 may control the transmission circuitry 108 to apply a prepulse as an OVS pulse to the subject P. An MR data acquisition process after application of the excitation pulse is similar to a known process, therefore, a description thereof is omitted. The processing circuitry 150 then uses the data acquisition function 134 to acquire MR data by performing a sequence including the series of at least seven suppression pulses. The data acquisition function 134 stores the MR data in the memory circuitry 132.

### Step S128

If acquisition of all of the MR data as to the region of interest is not completed (No in step S128), the processing in step S122 and the subsequent steps is performed for not-yet-acquired MR data. Upon completion of acquisition of all of the MR data as to the region of interest (Yes in step S128), the suppression sequence process ends.

The MRI apparatus 100 of the first embodiment described above acquires MR data by performing a sequence including a series of at least seven suppression pulses which are RF pulses with different flip angles. According to the MRI apparatus 100 of the first embodiment, at least one of the pulse intervals between two respective adjacent suppression pulses of the front half of the chronological series of suppression pulses is set to 70 ms or less.

Owing to such features, the MRI apparatus 100 of the first embodiment can attain higher suppression effects as shown in the analysis result of FIG. 3 in the first example, compared with the analysis result of FIG. 5 in the first comparative example and the analysis result of FIG. 7 in the second comparative example. As depicted in FIG. 3 in the first example, the MRI apparatus 100 of the first embodiment can maintain attenuation at approximately 1/10,000, even when the flip angles are offset (e.g., by ±20%) from the design flip angle (100% on the graph EG1), thereby achieving B1-insensitivity effects as designed. As such, the MRI apparatus 100 of the first embodiment can provide improved water suppression performance, compared with the first comparative example and the second comparative example.

In addition, according to the MRI apparatus 100 of the first embodiment, the interval between the last suppression pulse and the excitation pulse is set to 45 ms more, which corresponds to a time interval sufficient to be able to apply one or more prepulses while suppressing occurrence of MR signals due to the excitation pulse by using the series of suppression pulses. Namely, the MRI apparatus 100 the first embodiment allows setting of a longer interval between the last suppression pulse and the excitation pulse as shown in FIG. 2, FIG. 8, FIG. 10, FIG. 12, and FIG. 14, in comparison with the first comparative example of FIG. 4 and the second comparative example FIG. 6.

Consequently, the MRI apparatus 100 of the first embodiment enables arrangement of one or more prepulses between the last one of the series of suppression pulses and the excitation pulse in the sequence. Thereby, the MRI apparatus 100 of the first embodiment can allow the arrangement of one or more prepulses immediately prior to the excitation pulse according to a user's intention, resulting in attaining improved prepulse effects.

To implement the technical idea of the first embodiment by a data acquisition method, the data acquisition method includes acquiring magnetic resonance data by performing a sequence including a series of at least seven suppression pulses which are RF pulses with different flip angles. The procedure and effects of the suppression sequence process by the data acquisition method are similar to or the same as those in the first embodiment, therefore, a description thereof is omitted.

To implement the technical idea of the first embodiment by a data acquisition program, the data acquisition program causes a computer to acquire magnetic resonance data by performing a sequence including a series of at least seven suppression pulses which are RF pulses with different flip angles.

As an example, the data acquisition program may be installed in the computer of the MRI apparatus and loaded on the memory to be able to implement the suppression sequence process. In this case the computer program for causing the computer to execute the suppression sequence process can be stored and distributed in a storage medium such as a magnetic disk (e.g., hard disk), an optical disk (e.g., CD-ROM, DVD), or a semiconductor memory. In addition to being stored in the storage medium, the data acquisition program can be distributed using an electric communication function such as downloading via the Internet. The procedure and effects of the suppression sequence process by the data acquisition program are similar to or the same as those in the first embodiment, therefore, a description thereof is omitted.

### Second Embodiment

A second embodiment involves MR data acquisition implemented by setting at least one or a combination of the number of suppression pulses, the flip angles of the suppression pulses, and the pulse intervals among the suppression pulses in accordance with a user set repetition time (TR) or a duration for performing a suppression pulse train of the suppression pulses to be applied for suppression of the same MR signals. The duration for performing a suppression pulse train corresponds to a length of available time for implementing a higher degree of water suppression with the suppression pulse train in MRS, for example. The duration also corresponds to a length of available time for applying two or more suppression prepulses.

The input apparatus 141 receives an input of a TR or a duration for running a suppression pulse train by a user instruction. The input apparatus 141 stores the input TR or duration in the memory circuitry 132. The TR or duration is set in this manner. Additionally, the input apparatus 141 may receive an input of the number of suppression pulses. Thus, the number of suppression pulses in the sequence for MR data acquisition is set by the input. The input apparatus 141 corresponds to an input unit.

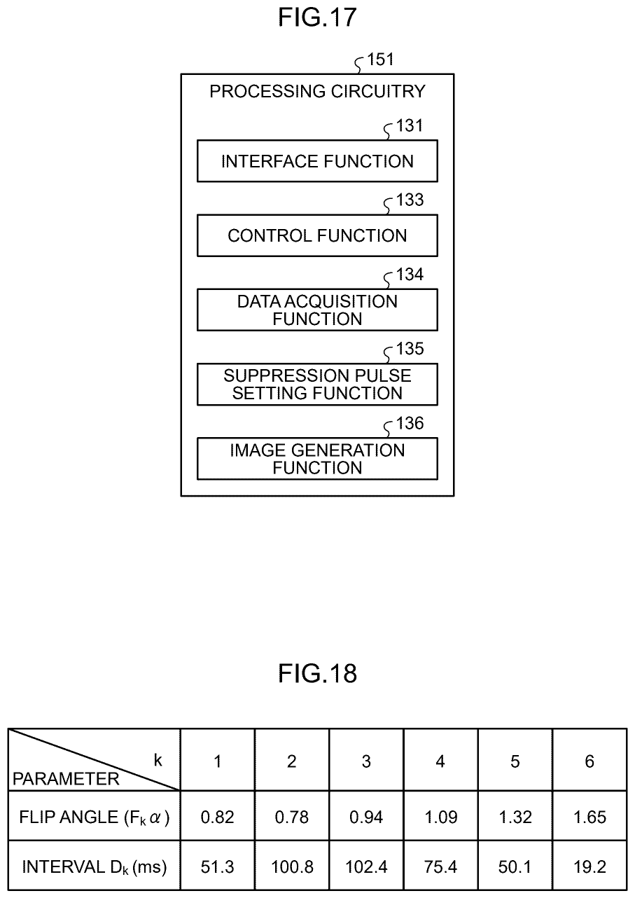

FIG. 17 is a schematic block diagram illustrating an example of the functional configuration of processing circuitry 151 according to the second embodiment. The processing circuitry 151 is incorporated in the computer 130 of the MRI apparatus 100. The processing circuitry 151 includes an interface function 131, a control function 133, a suppression pulse setting function 135, a data acquisition function 134, and an image generation function 136. Among the respective functions of the processing circuitry 151 of the second embodiment in FIG. 17, a description of the functions similar to those in the first embodiment is omitted. The rest of the elements of the MRI apparatus 100 in the second embodiment is similar to those in the first embodiment, so that a description of the overlapping functions of the elements shown in FIG. 1 is omitted.

The interface function 131 is configured to retrieve the TR or duration from the memory circuitry 132. The interface function 131 thus obtains the TR or duration.

The suppression pulse setting function 135 is configured to set at least one or a combination of the number of suppression pulses, flip angles of the suppression pulses, and pulse intervals among the suppression pulses in accordance with the preset TR or the duration. The suppression pulse train includes the number of suppression pulses, the flip angles of the suppression pulses, and the pulse intervals among the suppression pulses, and is optimized in advance in accordance with the number of suppression pulses and the TR or duration. The optimized suppression pulse train is stored in the memory circuitry 132 in association with the number of suppression pulses and the TR or duration. Namely, multiple suppression pulse trains associated with a combination of the number of suppression pulses and the TR or duration are stored in the memory circuitry 132. The suppression pulses included in the suppression pulse train are RF pulses with different flip angles.

The suppression pulse setting function 135 selects, identifies, or sets, as a sequence for use in MR data acquisition, a suppression pulse train associated with the input TR or duration from the optimized suppression pulse trains. In this manner, the suppression pulse setting function 135 adaptively changes the number of suppression pulses in accordance with the TR or duration, when setting at least one or a combination of the number of suppression pulses, the flip angles, and the pulse intervals. For example, the suppression pulse setting function 135 sets, as an MR-data acquisition sequence, a suppression pulse train including the number of suppression pulses, the number changed according to a user input TR or the duration, or adaptively changed relative to the TR. In this sequence, one or more prepulses are arranged between the chronologically last one of the suppression pulses and the excitation pulse.

In addition, the suppression pulse setting function 135 may select a suppression pulse train based on an additionally input number of suppression pulses. Consequently, the suppression pulse setting function 135 sets, as a MR-data acquisition sequence, at least one or a combination of the number of suppression pulses, the flip angles of suppression pulses, and the pulse intervals among suppression pulses in accordance with the preset TR or the duration. The processing circuitry 151 implementing the suppression pulse setting function 135 corresponds to a suppression pulse setting unit.

The following will describe the optimization of the number, the flip angles, and the pulse intervals of suppression pulses in the suppression pulse train. The suppression pulse setting function 135 optimizes the number, flip angles, and pulse intervals of the suppression pulses at least in relation to one another, in accordance with the TR or duration. For example, the suppression pulse setting function 135 optimizes at least one of the number, flip angles, and pulse intervals of the suppression pulses with reference to the TR or duration in such a manner that an overtime relative to the TR or duration is to be a minimum.

Specifically, the suppression pulse setting function 135 optimizes the number of suppression pulses, a flip angle αFₖ, and a pulse interval Dₖ by obtaining a longitudinal magnetization B_{Z}(tₖ₊₁) at a (k+1)^{-th} time tₖ₊₁ (k being an arbitrary natural number) to find the product of an absolute value of the longitudinal magnetization B_{Z}(tₖ₊₁) and a weight set depending on a reference angle α and a longitudinal relaxation time T₁, summing up the products for the longitudinal relaxation time T₁ and the reference angle α to obtain a total sum of the products, and minimizing the total sum. The product corresponds to a weighted addition of the absolute value |B_{Z}(tₖ₊₁)| of the longitudinal magnetization B_{Z}(tₖ₊₁). Examples of this optimization method include differential evolution.

The optimization represents, for example, minimization of the following Equation (3):

$$\text{?} {\sum }_{{T}_{1}} W ( α , {T}_{1} ) \vert {B}_{z} ( {t}_{k + 1} ) \vert \qquad ( 3 )$$

$$\text{?} \text{indicates text missing or illegible when filed}$$

Thereby, the suppression pulse setting function 135 sets one or a combination of the number of suppression pulses, the flip angles, the pulse intervals all of which are optimized, in accordance with the TR or the above duration.

In place of calculating Equation (3), measured values by the MRI apparatus may be used. The difference between Equation (3) and Equation (2) is in that the absolute value |B_{Z}(tₖ₊₁)| of the longitudinal magnetization B_{Z}(tₖ₊₁) is multiplied by the weight W(α, T₁) according to the reference angle α and the longitudinal relaxation time T₁. The weight W(α, T₁) is predefined according to the reference angle α and the longitudinal relaxation time T₁ for storage in the memory circuitry 132.

Equation (3) may additionally include an amount exceeding the preset TR as a penalty term. The penalty term may be an amount exceeding the duration for execution of the suppression pulse train, in addition to the TR. The penalty term may be added to Equation (2).

In the following, the penalty term is defined as an amount exceeding the TR for specificity. The TR as the penalty term is predefined for storage in the memory circuitry 132. In this case the optimization is, for example, feasible by minimization of the following Equation (4):

$$\text{?} {\sum }_{{T}_{1}} W ( α , {T}_{1} ) \vert {B}_{z} ( {t}_{k + 1} ) \vert + λ Δ TR \qquad ( 4 )$$

$$\text{?} \text{indicates text missing or illegible when filed}$$

The second term of Equation (4) is the penalty term. The penalty term is the product of a parameter λ and an amount ΔTR exceeding TR. The parameter λ is preset or suitably adjusted for storage in the memory circuitry 132. The TR exceeding amount ΔTR represents a difference between the preset TR (hereinafter, a set TR) and a total amount of time ΣₖDₖ taken for each of iterative computation processes for the minimization of Equation (4), for example. In place of calculating the first term of Equation (4), measured values by the MRI apparatus may be used.

Specifically, the suppression pulse setting function 135 computes the pulse interval Dₖ in each of iterative computation processes for the minimization of Equation (4) to find the total amount of time ΣₖDₖ from the resultant pulse intervals Dₖ. The suppression pulse setting function 135 then computes the TR exceeding amount ΔTR by subtracting the set TR from the total amount of time ΣₖDₖ. Namely, the suppression pulse setting function 135 computes the TR exceeding amount ΔTR in each iterative computation process for the minimization of Equation (4), to perform the minimization of Equation (4) using the resultant exceeding amount ΔTR.

In other words, the suppression pulse setting function 135 optimizes the number of suppression pulses, the flip angles αFₖ, and the pulse intervals Dₖ in the following manner. The longitudinal magnetization B_{Z}(tₖ₊₁) at the (k+1)^{th} time is obtained based on the flip angle of the k^{th} one (k being a natural number) of the suppression pulses to be applied for suppression of the same MR signals, the k^{th} pulse interval Dₖ in which no suppression pulses in the suppression pulse train are applied, the longitudinal relaxation time T₁ for the MR signals to be suppressed, and the longitudinal magnetization B₀ in the equilibrium state. Then, the absolute value |B_{Z}(tₖ₊₁)| of the longitudinal magnetization is multiplied by the weight W(α, T₁) set according to the reference flip angle α and the longitudinal relaxation time T₁ to obtain the product W(α, T₁)|B_{Z}(tₖ₊₁)| and sum up the products W(α, T₁)|B_{Z}(tₖ₊₁)| for the longitudinal relaxation time T₁ and the reference angle α of the flip angles to find the total sum of the products (Equation (3)). The number of suppression pulses, the flip angles αFₖ, and the pulse intervals Dₖ can be then optimized by minimization of the function (Equation (4)) which is obtained by adding the amount ΔTR exceeding the preset TR as a penalty term λΔTR to the total sum of the products.

The objects to be optimized are not limited to the flip angle αFₖ and the pulse interval Dₖ. For instance, the suppression pulse setting function 135 may optimize the shape of suppression pulses (pulse shape) by the Shinnar-Le Roux algorithm. The optimized pulse shape can be implemented as an SLR pulse, for example.

An example of using six suppression pulses is now explained. FIG. 18 depicts an example of optimized parameters Fₖ and Dₖ as a sixth example. In this example, the total amount of time (sum of intervals Dₖ(ΣₖDₖ)) from a start of application of water suppression pulses to application of an excitation pulse is 399.1 ms (about 400 ms). The number of suppression pulses (water suppression pulses) is six, as shown in FIG. 18.

As shown in FIG. 18, the flip angles of the six water suppression pulses are set to 0.82×α, 0.78×α, 0.94×α, 1.09×α, 1.32×α, and 1.65×α where α is a reference angle, in the order of application thereof (in the order of k). The intervals (ms) between two respective adjacent ones of the six water suppression pulses and the interval (ms) between the last one of the water suppression pulses and the excitation pulse are 51.3, 100.8, 102.4, 75.4, 50.1, and 19.2 in the order of application of the water suppression pulses.

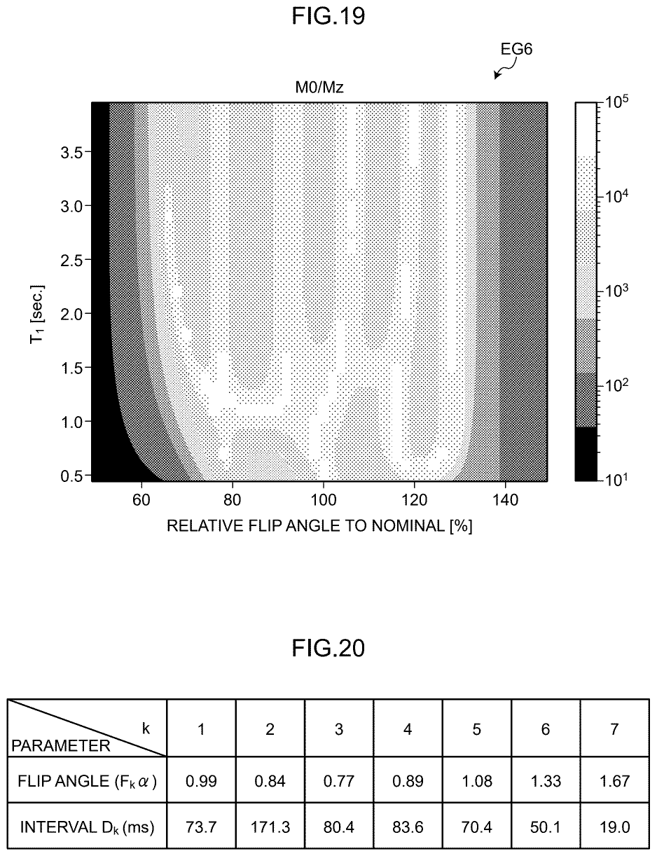

FIG. 19 is a graph depicting a result of characteristic analysis using the parameter set (hereinafter, a sixth optimal parameter set) shown in FIG. 18 according to the sixth example, as an example. In FIG. 19 the result of characteristic analysis in the sixth example was computed through a simulation using the sixth optimal parameter set when α=90 degrees, for example. The characteristic analysis result is also referred to as a slice profile. In the graph EG6 of FIG. 19 showing the characteristic analysis result in the sixth example, the vertical axis indicates a T₁ value and the horizontal axis indicates a ratio of flip angles in the simulation to nominal flip angles (design flip angles).

In the graph EG6 of FIG. 19 of the sixth example, the ratios of attenuation of the water suppression pulses are indicated by different kinds of hatching. In a colored graph EG6 of FIG. 19, attenuation of 1/100,000 is represented in white, attenuation of 1/10,000 is represented in green, attenuation of about 1/1,100 is represented in intermediate color (orange) between red and green, attenuation of about 1/1,000 is represented in red, attenuation of about 1/300 is represented in purple, attenuation of about 1/100 is represented in blue, and attenuation of about 1/10 is represented in black. As such, the white to green regions indicate preferable attenuation characteristics.

In comparison, in the graph EG6 showing the characteristic analysis result of FIG. 19 in the sixth example, the attenuation area of 1/100,000 to 1/1,000 well matches the T₁ values of CSF, GM, and WM, as compared with that in the graph CG1 of FIG. 5 in the first comparative example and the graph CG2 of FIG. 7 in the second comparative example. According to the characteristic analysis result in the graph EG6 of FIG. 19 in the sixth example, thus, it can be said that the signal suppression effects of the suppression pulses in the sixth example are improved from those in the first and second comparative examples.

The exemplary parameters Fₖ and Dₖ in the present embodiment are not limited to the sixth optimal parameter set. The following will explain the use of seven suppression pulses by way of example. FIG. 20 depicts an example of optimized parameters using seven suppression pulses (water suppression pulses). In FIG. 20, the total amount of time (sum of intervals Dₖ (ΣₖDₖ)) from a start of application of water suppression pulses to application of an excitation pulse is 548.5 ms (about 550 ms).

As shown in FIG. 20, the flip angles of the seven water suppression pulses are set to 0.99×α, 0.84×α, 0.77×α, 0.89×α, 1.08×α, 1.33×α, and 1.67×α where α is a reference angle, in the order of application thereof (in the order of k). The intervals (ms) between two respective adjacent ones of the seven water suppression pulses and the interval (ms) between the last one of the water suppression pulses and the excitation pulse are 73.7, 171.3, 80.4, 83.6, 70.4, 50.1, and 19.0 in the order of application of the water suppression pulses.

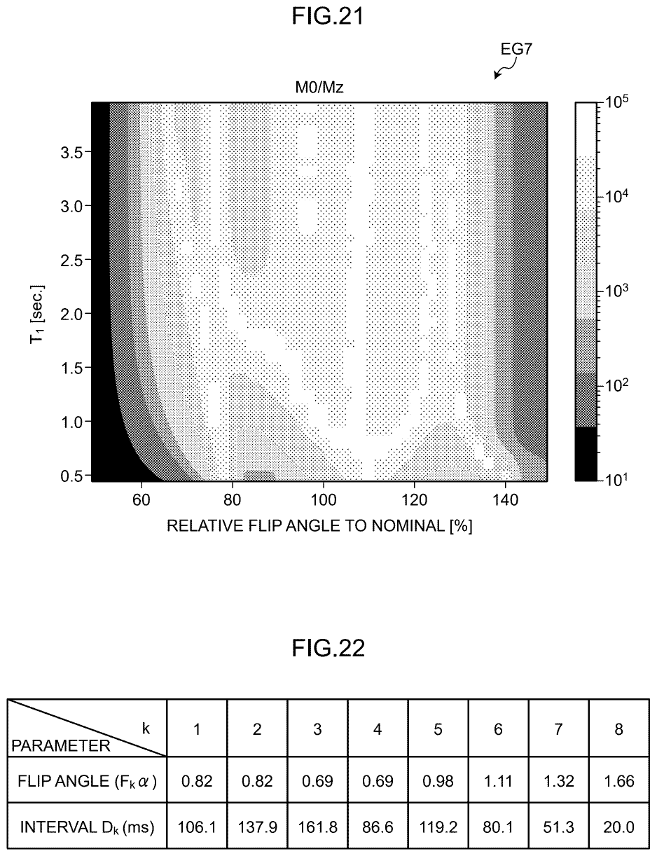

FIG. 21 is a graph depicting a result of characteristic analysis using the parameter set (hereinafter, a seventh optimal parameter set) shown in FIG. 20 according to a seventh example, as an example. In FIG. 21 the result of characteristic analysis in the seventh example was computed through a simulation using the seventh optimal parameter set when α=90 degrees, for example. The characteristic analysis result is also referred to as a slice profile. In the graph EG7 of FIG. 21 showing the characteristic analysis result in the seventh example, the vertical axis indicates a T₁ value and the horizontal axis indicates a ratio of flip angles in the simulation to nominal flip angles (design flip angles).

In the graph EG7 of FIG. 21 of the seventh example, the ratios of attenuation of the water suppression pulses are indicated by different kinds of hatching. In a colored graph EG7 of FIG. 21, attenuation of 1/100,000 is represented in white, attenuation of 1/10,000 is represented in green, and attenuation of about 1/1,100 is represented in intermediate color (orange) between red and green, attenuation of about 1/1,000 is represented in red, attenuation of about 1/300 is represented in purple, attenuation of about 1/100 is represented in blue, and attenuation of about 1/10 is represented in black. As such, the white to green regions indicate preferable attenuation characteristics.

In comparison, the graph EG7 showing the characteristic analysis result of FIG. 21 in the seventh example has a wider attenuation area of 1/100,000 to 1/1,000 which well matches the T₁ values of CSF, GM, and WM, as compared with the graph CG1 of FIG. 5 in the first comparative example and the graph CG2 of FIG. 7 in the second comparative example. According to the characteristic analysis result in the graph EG7 of FIG. 21 in the seventh example, thus, it can be said that the signal suppression effects of the suppression pulses in the seventh example are improved from those in the first and second comparative examples.

The exemplary parameters Fₖ and Dₖ in the present embodiment are not limited to the sixth optimal parameter set and the seventh optimal parameter set. FIG. 22 depicts an example of optimized parameters using eight suppression pulses (water suppression pulses) as an eighth example. In FIG. 22, the total amount of time (sum of intervals Dₖ (ΣₖDₖ)) from a start of application of water suppression pulses to application of an excitation pulse is 762.9 ms (about 760 ms).

As depicted in FIG. 22, the flip angles of the eight water suppression pulses are set to 0.82×α, 0.82×α, 0.69×α, 0.69×α, 0.98×α, 1.11×α, 1.32×α, and 1.66×α where a is a reference angle, in the order of application thereof (in the order of k). The intervals (ms) between two respective adjacent ones of the eight suppression pulses and the interval (ms) between the last one of the water suppression pulses and the excitation pulse are 106.1, 137.9, 161.8, 86.6, 119.2, 80.1, 51.3, and 20.0 in the order of application of the water suppression pulses.

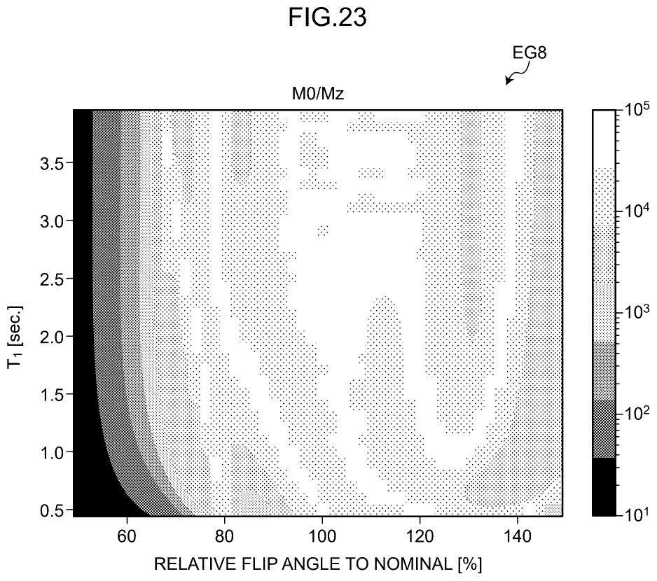

FIG. 23 is a graph depicting a result of characteristic analysis using the parameter set (hereinafter, an eighth optimal parameter set) shown in FIG. 22 according to an eighth example, as an example. In FIG. 23 the result of characteristic analysis in the eighth example was computed through a simulation using the eighth optimal parameter set when α=90 degrees, for example. The characteristic analysis result is also referred to as a slice profile. In the graph EG8 of FIG. 23 showing the characteristic analysis result in the eighth example, the vertical axis indicates a T₁ value and the horizontal axis indicates a ratio of flip angles in the simulation to nominal flip angles (design flip angles).

In the graph EG8 of FIG. 23 of the eighth example, the ratios of attenuation of the water suppression pulses are indicated by different kinds of hatching. In a colored graph EG8 of FIG. 23, attenuation of 1/100,000 is represented in white, attenuation of 1/10,000 is represented in green, and attenuation of about 1/1,100 is represented in intermediate color (orange) between red and green, attenuation of about 1/1,000 is represented in red, attenuation of about 1/300 is represented in purple, attenuation of about 1/100 is represented in blue, and attenuation of about 1/10 is represented in black. As such, the white to green regions indicate preferable attenuation characteristics.

In comparison, the graph EG8 showing the characteristic analysis result of FIG. 23 in the eighth example has a wider attenuation area of 1/100,000 to 1/1,000 which matches the T₁ values of CSF, GM, and WM, as compared with that in the graph CG1 of FIG. 5 in the first comparative example and the graph CG2 of FIG. 7 in the second comparative example. According to the characteristic analysis result in the graph EG8 of FIG. 23 in the eighth example, thus, it can be said that the signal suppression effects of the suppression pulses in the eighth example are improved from those in the first and second comparative examples.

With respect to the sixth to eighth parameter sets, the multiple suppression pulses have different flip angles unlike the suppression pulses in the first and second comparative examples. Namely, according to the sixth to eighth examples, a signal suppressible sequence (suppression sequence) is constituted of RF pulses (suppression pulses) having different flip angles. In the suppression sequence, one or more prepulses as OVS pulses can be arranged between the last one of the series of suppression pulses and the excitation pulse.

The data acquisition function 134 performs a sequence (suppression sequence) including a suppression pulse train based on the number of suppression pulses, the flip angles, and the pulse intervals to thereby acquire MR data. The processing circuitry 151 implementing the data acquisition function 134 corresponds to a data acquisition unit. The operations of the data acquisition function 134 are in conformity with those in the embodiments, therefore, a description thereof is omitted.

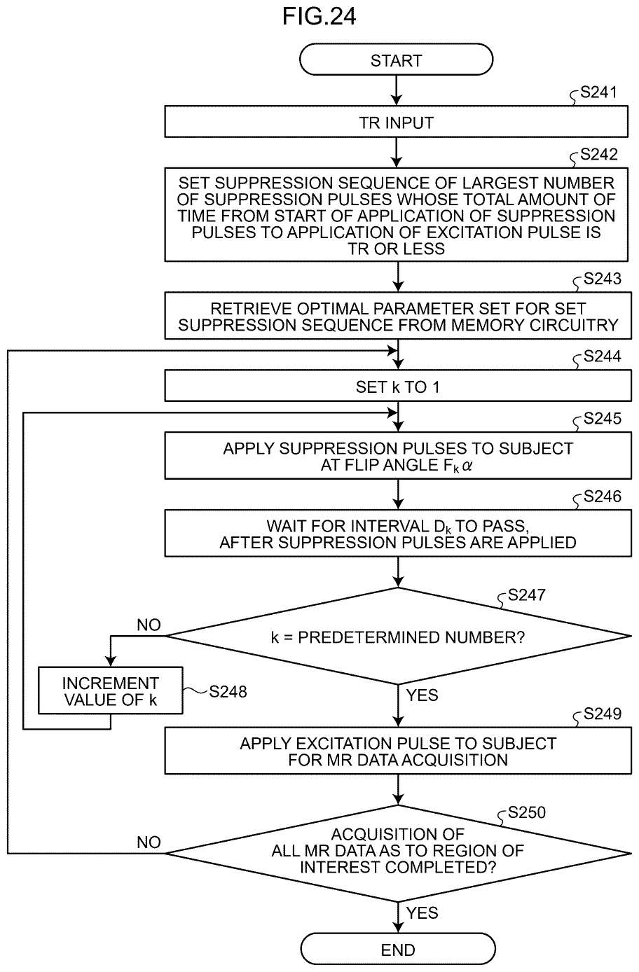

The functions performed by the processing circuitry 151 of the second embodiment have been described above. The following will describe a process of setting and performing a suppression sequence (hereinafter, suppression sequence execution process) by the processing circuitry 151. FIG. 24 is a flowchart illustrating a suppression sequence execution procedure, as an example.

### Suppression Sequence Execution Process

### Step S241

A TR is input according to a user instruction via the input apparatus 141. Alternatively, a duration for performing a suppression pulse train may be input in place of the TR. In addition, the processing circuitry 151 may use the interface function 131 to obtain a user's examination order from the radiology information system (RIS) in place of the TR or duration input. In this case, the processing circuitry 151 may use the suppression pulse setting function 135 to set the TR based on the examination order. According to another user instruction, the number of suppression pulses may also be input via the input apparatus 141.

### Step S242

The processing circuitry 151 uses the suppression pulse setting function 135 to identify multiple suppression pulse trains whose total amount of time from a start of application of suppression pulses to application of an excitation pulse is the TR or less. The suppression pulse setting function 135 then identifies a suppression pulse train of a largest number of suppression pulses (hereinafter, a largest-number pulse train) among the multiple suppression pulse trains. The suppression pulse setting function 135 next retrieves the largest-number pulse train from the memory circuitry 132 to set a suppression sequence using the largest-number pulse train.

Alternatively, the suppression pulse setting function 135 may optimize the number of suppression pulses, the flip angles, and the pulse intervals by the differential evolution method using Equation (3), for example, in a such a manner that the total amount of time from the start of application of the suppression pulses to the application of the excitation pulse is to be the TR or less. Specifically, the suppression pulse setting function 135 optimizes the number of suppression pulses, the flip angles, and the pulse intervals by applying Equation (4) to the differential evolution method. Further, the suppression pulse setting function 135 may also optimize the pulse shape of the suppression pulses as SLR pulses based on the optimized flip angles.

In response to an input of the number of suppression pulses, the suppression pulse setting function 135 may set the suppression sequence to match the input number of suppression pulses. Alternatively, in response to an input of the number of suppression pulses, the suppression pulse setting function 135 may optimize the number of suppression pulses, the flip angles, and the pulse intervals by Equation (3) or Equation (4) so as to match the input number of suppression pulses.

### Step S243

Prior to running the suppression sequence, the processing circuitry 151 uses the data acquisition function 134 to retrieve the optimal parameter set for the identified suppression pulse train from the memory circuitry 132. The processing from steps S244 to S250 is similar to steps S122 to 128, therefore, a description thereof is omitted.

The MRI apparatus 100 of the second embodiment as described above sets at least one or a combination of the number of suppression pulses, the flip angles of the suppression pulses, and the pulse intervals among the suppression pulses in accordance with a preset TR or a duration for performing a suppression pulse train of the suppression pulses to be applied for suppression of the same MR signals, to acquire MR data by performing a sequence including the suppression pulse train based on the set number of suppression pulses, flip angles, and pulse intervals.

For instance, the MRI apparatus 100 of the second embodiment optimizes the number of suppression pulses, the flip angles, the pulse intervals at least relative to one another in accordance with the TR or the duration. According to the MRI apparatus 100 of the second embodiment, the suppression pulses are RF pulses with different flip angles. In addition, the MRI apparatus 100 of the second embodiment employs the sequence (suppression sequence) in which one or more prepulses are arranged between the chronologically last one of the suppression pulses and the excitation pulse.

Moreover, the MRI apparatus 100 of the second embodiment optimizes the number of suppression pulses, the flip angles, and the pulse intervals by obtaining the longitudinal magnetization at the (k+1)^{th} time based on the flip angle of the k^{th} one (k being a natural number) of the suppression pulses to be applied for suppression of the same MR signals, the k^{th} pulse interval, the longitudinal relaxation time T₁, and the longitudinal magnetization in the equilibrium state; obtaining the product W(α T₁)|B_{Z}(tₖ₊₁)| of the absolute value |B_{Z}(tₖ₊₁)| of the longitudinal magnetization at the (k+1)^{th} time and the weight W(α, T₁) set according to the reference flip angle α and the longitudinal relaxation time T₁; summing up the products W(α T₁)|B_{Z}(tₖ₊₁)| for the longitudinal relaxation time T₁ and the reference angle α of the flip angles to find the total sum of the products (Equation (3)); and minimizing the total sum. Then, the MRI apparatus 100 sets one or a combination of the optimized number of suppression pulses, the optimized flip angles, and the optimized pulse intervals in accordance with the TR or the above duration.

In addition, the MRI apparatus 100 of the second embodiment optimizes at least one of the number of suppression pulses, the flip angles, the pulse intervals with reference to the TR or the duration in such a manner that an overtime from the TR or duration is to be a minimum. As an example, the MRI apparatus 100 of the second embodiment optimizes the number of suppression pulses, the flip angles, the pulse intervals by minimizing the function (Equation (4)) that is found by adding the amount ΔTR exceeding the preset repetition time to the total sum (Equation (3)) as the penalty term λΔTR.

Owing to such features, in comparison with the analysis results of FIGS. 5 and 7 in the first and second comparative examples, the MRI apparatus 100 of the second embodiment can exert higher suppression effects as exhibited in the analysis results of the sixth to eighth examples, irrespective of the number of suppression pulses and the pulse intervals.

Moreover, the MRI apparatus 100 of the second embodiment allows an input of the TR or duration. In this case, in setting at least one or a combination of the number of suppression pulses, the flip angles, the pulse intervals, the MRI apparatus 100 of the second embodiment adaptively changes the number of suppression pulses in line with the input TR or duration.

For example, the MRI apparatus 100 of the second embodiment selects a largest-number pulse train from among the multiple suppression pulse trains as optimized not to exceed the TR or duration. Alternatively, the MRI apparatus 100 of the second embodiment adaptively changes the number of suppression pulses to achieve higher suppression effects in a shorter length of time than the TR or duration plus a predetermined time (e.g., several dozen ms).

The term “adaptively” herein signifies setting a suppression pulse train with reference to the TR or duration while suitably changing the number of suppression pulses, so as to attain higher suppression effects, for example. Thus, the MRI apparatus 100 of the second embodiment adaptively changes the overall prepulse configuration (flip angles, pulse intervals, pulse shape) in line with a TR or a duration available for a suppression pulse train. In this manner, the MRI apparatus 100 of the second embodiment can set a suppression pulse train that exerts highest suppression effects according to a user intended TR or the above duration, for example, as shown in FIG. 18, FIG. 20, and FIG. 22. The rest of the effects are similar to or the same as those of the second embodiment, therefore, a description thereof is omitted.

To implement the technical idea of the second embodiment by a data acquisition method, the data acquisition method includes setting, in accordance with a preset TR or a duration for performing a suppression pulse train of suppression pulses to be applied for suppression of the same MR signals, at least one or a combination of the number of the suppression pulses, the flip angles of the suppression pulses, and the pulse intervals between the suppression pulses; and acquiring MR data by performing a sequence including the suppression pulse train based on the number of the suppression pulses, the flip angles, and the pulse intervals.

To implement the technical idea of the second embodiment by a data acquisition program, the data acquisition program causes the computer to perform setting, in accordance with a preset TR or a duration for performing a suppression pulse train of suppression pulses to be applied for suppression of the same MR signals, at least one or a combination of the number of the suppression pulses, the flip angles of the suppression pulses, and the pulse intervals between the suppression pulses; and acquiring MR data by performing a sequence including the suppression pulse train based on the number of the suppression pulses, the flip angles, and the pulse intervals.

As an example, the data acquisition program may be installed in the computer of the MRI apparatus and loaded on the memory to be able to implement the suppression sequence execution process. In this case the computer program for causing the computer to execute the suppression sequence execution process can be stored and distributed in a storage medium such as a magnetic disk (e.g., hard disk), an optical disk (e.g., CD-ROM, DVD), or a semiconductor memory. In addition to being stored in the storage medium, the data acquisition program can be distributed using an electric communication function such as downloading via the Internet. The procedure and effects of the suppression sequence execution process are similar to or the same as those in the second embodiment, therefore, a description thereof is omitted.

According to at least one of the embodiments and examples as above, it is made possible to provide improved MR-signal suppression.

While predetermined embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

With respect to the various embodiments described above, subjoinders describing an aspect and selective features of the inventions will be presented in the following.

### Subjoinder 1

A magnetic resonance imaging apparatus includes a data acquisition unit configured to acquire magnetic resonance data by performing a sequence including a series of at least seven suppression pulses, wherein the suppression pulses are RF pulses with different flip angles.

### Subjoinder 2

In the sequence, one or more prepulses may be arranged between a chronologically last suppression pulse of the series of suppression pulses and an excitation pulse.

### Subjoinder 3

At least one of pulse intervals between two respective adjacent suppression pulses of the front half of the chronological series of suppression pulses may be set to 70 ms or less.

### Subjoinder 4

The interval between the last one of the suppression pulses and the excitation pulse may be set to 45 ms or more and may represent a time interval during which one or more prepulses can be applied while suppressing occurrence of magnetic resonance signals resulting from the excitation pulse by using the series of suppression pulses.

### Subjoinder 5

A data acquisition method is provided for acquiring magnetic resonance data by performing a sequence including a series of at least seven suppression pulses, wherein the suppression pulses are RF pulses with different flip angles.

### Subjoinder 6

A data acquisition program is provided for causing a computer to perform acquiring magnetic resonance data by performing a sequence including a series of at least seven suppression pulses, wherein the suppression pulses are RF pulses with different flip angles.

What is claimed is:

1. A magnetic resonance imaging apparatus comprising processing circuitry configured to:
set, in accordance with a preset repetition time (TR) or a duration for performing a suppression pulse train of suppression pulses to be applied for suppression of same magnetic resonance signals, at least one or a combination of a number of the suppression pulses, flip angles of the suppression pulses, and pulse intervals between the suppression pulses; and
acquire magnetic resonance data by performing a sequence including the suppression pulse train based on the number of the suppression pulses, the flip angles, and the pulse intervals.

2. The magnetic resonance imaging apparatus according to claim 1, wherein
the processing circuitry is further configured to optimize the number of the suppression pulses, the flip angles, and the pulse intervals at least relative to one another in accordance with the repetition time or the duration.

3. The magnetic resonance imaging apparatus according to claim 1, further comprising:
an input apparatus that allows an input of the repetition time or the duration.

4. The magnetic resonance imaging apparatus according to claim 1, wherein
the processing circuitry is further configured to adaptively change the number of the suppression pulses in accordance with the repetition time or the duration, when setting at least one or a combination of the number of the suppression pulses, the flip angles, and the pulse intervals.

5. The magnetic resonance imaging apparatus according to claim 1, wherein
the processing circuitry is further configured to optimize at least one of the number of the suppression pulses, the flip angles, or the pulse intervals with reference to the repetition time or the duration in such a manner that an overtime from the repetition time or the duration is to be a minimum.

6. The magnetic resonance imaging apparatus according to claim 1, wherein the processing circuitry is further configured to:
optimize least one or a combination of the number of the suppression pulses, the flip angles, and the pulse intervals by:
obtaining a longitudinal magnetization at a (k+1)^{th} time based on a flip angle of a k^{th} suppression pulse of the suppression pulses to be applied for suppression of the same magnetic resonance signals, a k^{th} pulse interval in which no suppression pulses in the suppression pulse train are applied, a longitudinal relaxation time for the magnetic resonance signals to be suppressed, and a longitudinal magnetization in an equilibrium state, k being a natural number,
obtaining a product of an absolute value of the longitudinal magnetization at the (k+1)^{th} time and a weight set according to the longitudinal relaxation time and a reference angle of the flip angles,
summing up products of the absolute value and the weight for the longitudinal relaxation time and the reference angle of the flip angles to find a total sum of the products, and
minimizing the total sum, and
set one or a combination of the optimized number of the suppression pulses, the optimized flip angles, and the optimized pulse intervals in accordance with the repetition time or the duration.

7. The magnetic resonance imaging apparatus according to claim 6, wherein the processing circuitry is further configured to:
obtain a function by adding an amount exceeding the preset repetition time to the total sum as a penalty term, and
optimize the number of the suppression pulses, the flip angles, and the pulse intervals by minimizing the function.

8. The magnetic resonance imaging apparatus according to claim 1, wherein
the suppression pulses are RF pulses with different flip angles.

9. The magnetic resonance imaging apparatus according to claim 1, wherein
in the sequence, one or more prepulses are arranged between a chronologically last suppression pulse of the suppression pulses and an excitation pulse.

10. A data acquisition method comprising:
setting, in accordance with a preset repetition time (TR) or a duration for performing a suppression pulse train of suppression pulses to be applied for suppression of same magnetic resonance signals, at least one or a combination of a number of the suppression pulses, flip angles of the suppression pulses, and pulse intervals between the suppression pulses; and
acquiring magnetic resonance data by performing a sequence including the suppression pulse train based on the number of the suppression pulses, the flip angles, and the pulse intervals.

11. A computer-readable, nonvolatile storage medium storing a data acquisition program that causes a computer to perform:
setting, in accordance with a preset repetition time (TR) or a duration for performing a suppression pulse train of suppression pulses to be applied for suppression of same magnetic resonance signals, at least one or a combination of a number of the suppression pulses, flip angles of the suppression pulses, and pulse intervals between the suppression pulses; and
acquiring magnetic resonance data by performing a sequence including the suppression pulse train based on the number of the suppression pulses, the flip angles, and the pulse intervals.
